(19) United States
(12) Patent Application Publication
(10) Pub. No.: US 2019/0333974 A1
(43) Pub. Date: Oct. 31, 2019

(54) ARRAY SUBSTRATE AND METHOD OF MANUFACTURING THE SAME, DISPLAY PANEL, AND DISPLAY DEVICE

(71) Applicant: BOE TECHNOLOGY GROUP CO., LTD., Beijing (CN)

(72) Inventors: Bo JIANG, Beijing (CN); Qian JIN, Beijing (CN); Haibin ZHU, Beijing (CN); Liwen DONG, Beijing (CN)

(21) Appl. No.: 16/386,133

(22) Filed: Apr. 16, 2019

(30) Foreign Application Priority Data
Apr. 28, 2018 (CN) 201810408105.9

(51) Int. Cl. H01L 27/32; G03F 7/00

(52) U.S. Cl. CPC H01L 27/3246; G03F 7/0007; H01L 27/3283

(57) ABSTRACT

A method of manufacturing an array substrate includes: providing a base substrate; forming a pixel defining layer including a plurality of barrier walls on one side of the base substrate; and modifying a surface to be modified of each of at least one barrier wall of the plurality of barrier walls, so that a surface of a corresponding one of the at least one barrier wall used for forming a pixel region includes a lyophilic surface and a lyophobic surface.

### CROSS-REFERENCE TO RELATED APPLICATION

This application claims priority to Chinese Patent Application No. 201810408105.9, filed on Apr. 28, 2018, titled “AN ARRAY SUBSTRATE AND METHOD OF MANUFACTURING THE SAME, DISPLAY DEVICE”, which is incorporated herein by reference in its entirety.

### TECHNICAL FIELD

The present disclosure relates to the field of display technologies, and in particular, to an array substrate and a method of manufacturing the same, a display panel and a display device.

### BACKGROUND

Organic light-emitting diode (OLED) displays have been widely used in various kinds of display devices including computers, mobile phones, and other electronic products due to their advantages of self-illumination, light weight, thin thickness, low power consumption, high contrast, high color gamut, and flexible display.

### SUMMARY

In an aspect, a method of manufacturing an array substrate is provided. The method includes: providing a base substrate; forming a pixel defining layer including a plurality of barrier walls on one side of the base substrate; and modifying a surface to be modified of each of at least one barrier wall of the plurality of barrier walls, so that a surface of a corresponding one of the at least one barrier wall used for forming a pixel region includes a lyophilic surface and a lyophobic surface.

In some embodiments, the step of modifying a surface to be modified of at least one barrier wall, includes: providing a mask on a surface of the at least one barrier wall facing away from the base substrate, wherein the mask includes at least one opening, and an orthographic projection of the surface to be modified of each of the at least one barrier wall on the base substrate is within an orthographic projection of a corresponding one the at least oneopening of the mask on the base substrate; and injecting plasma into the surface to be modified of each of the at least one barrier wall exposed in the corresponding one of the at least one opening of the mask, so as to modify a wetting property of the surface to be modified.

In some embodiments, a surface of the mask close to the base substrate is in a same plane as a top surface of the at least one barrier wall away from the base substrate.

In some embodiments, the plurality of barrier walls are formed from a lyophobic material, and the step of modifying a surface to be modified of each of at least one barrier wall, includes: performing lyophilic treatment on the surface to be modified of each of the at least one barrier wall.

In some embodiments, the lyophobic material is selected from a group consisting of fluorinated polyimide, fluorinated polymethyl methacrylate, polysiloxane and combination thereof.

In some embodiments, the step of performing lyophilic treatment on the surface to be modified of the at least one barrier wall, includes: injecting at least one of O₂ plasma, N₂ plasma, or NH₃ plasma into the surface to be modified of each of the at least one barrier wall, so as to modify the surface to be modified of each of the at least one barrier wall from a lyophobic surface to a lyophilic surface.

In some embodiments, the plurality of barrier walls are formed from a lyophilic material; and the step of modifying a surface to be modified of at least one barrier wall, includes: performing lyophobic treatment on the surface to be modified of each of the at least one barrier wall.

In some embodiments, the lyophilic material is selected from a group consisting of a starch polymer, a cellulose polymer, a polyvinyl alcohol polymer, a polyacrylate polymer, a polyoxyethylene polymer, and combination thereof.

In some embodiments, the step of performing lyophobic treatment on the surface to be modified of the at least one barrier wall, includes: injecting at least one of NF₃ plasma, CF₄ plasma, or SF₆ plasma into the surface to be modified of each of the at least one barrier wall, so as to modify the surface to be modified of each of the at least one barrier wall from a lyophilic surface to a lyophobic surface.

In some embodiments, the step of modifying a surface to be modified of each of at least one barrier wall, includes: spraying a photoresist on an original surface of each of the at least one barrier wall used for forming a pixel region, and exposing and developing the photoresist so that the surface to be modified of each of the at least one barrier wall is exposed; and using a chemical reagent to chemically react with the exposed surface to be modified of each of the at least one barrier wall to modify a wetting property of the surface to be modified.

In another aspect, an array substrate is provided. The array substrate includes a base substrate and a pixel defining layer disposed on one side of the base substrate. The pixel defining layer includes a plurality of barrier walls, and a surface of each of at least one barrier wall of the plurality of barrier walls used for forming a pixel region includes a lyophilic surface and a lyophobic surface. One of the lyophilic surface and the lyophobic surface is a modified surface.

In some embodiments, the lyophilic surface of each of the at least one barrier wall is bordered by the lyophobic surface of a same barrier wall, and the lyophilic surface is disposed on a side of the lyophobic surface close to the base substrate.

In some embodiments, a surface of each of the at least one barrier wall close to the base substrate is used as a reference surface. In a direction from the base substrate to the at least one barrier wall, a height of one of the at least one barrier wall is a first height, a height of a border between the lyophilic surface and the lyophobic surface of the one of the at least one barrier wall is a second height. The second height is 5%˜20% of the first height. Alternatively, the second height is approximately 5%˜20% of the first height.

In some embodiments, the first height is 1 μm˜5 μm. Alternatively, the first height is approximately 1 μm˜5 μm. The second height is 0.1 μm˜0.5 μm. Alternatively, the second height is approximately 0.1 μm˜0.5 μm.

In some embodiments, the lyophilic surface of the at least one barrier wall includes at least one of a C—O bond, a C—N bond, or a C—H bond.

In some embodiments, the lyophobic surface of the at least one barrier wall includes at least one of a C—F bond or a C—Si bond.

In yet another aspect, a display panel is provided, which includes the array substrate described above.

In yet another aspect, a display device is provided, which includes the display panel described above.

### BRIEF DESCRIPTION OF THE DRAWINGS

In order to describe technical solutions in embodiments of the present disclosure more clearly, the accompanying drawings to be used in the description of disclosure will be introduced briefly. Obviously, the accompanying drawings to be described below are merely some embodiments of the present disclosure, and a person of ordinary skill in the art can obtain other drawings according to these drawings without paying any creative effort.

FIG. 1 is a schematic diagram showing a structure of an array substrate in the related art;

FIG. 2 is a schematic diagram showing a structure of an array substrate according to some embodiments of the present disclosure;

FIG. 3 is a schematic diagram showing a structure of another array substrate according to some embodiments of the present disclosure;

FIG. 4 is a flow chart of a method of manufacturing the array substrate shown in FIG. 3 according to some embodiments of the present disclosure;

FIG. 5 is a schematic diagram showing a structure of a mask according to some embodiments of the present disclosure;

FIG. 6 is a schematic diagram showing a structure of another mask according to some embodiments of the present disclosure;

FIG. 7 is a schematic diagram showing a structure of yet another array substrate according to some embodiments of the present disclosure;

FIG. 8 is a flow chart of a method of manufacturing the array substrate shown in FIG. 7 according to some embodiments of the present disclosure;

FIG. 9 is a flow chart of a method of manufacturing an array substrate according to some embodiments of the present disclosure; and

FIG. 10 is a schematic diagram showing a structure of a display device according to some embodiments of the present disclosure.

### DETAILED DESCRIPTION

The technical solutions in the embodiments of the present disclosure will be described clearly and completely below with reference to the accompanying drawings in the embodiments of the present disclosure. Obviously, the described embodiments are merely some but not all of embodiments of the present disclosure. All other embodiments made on the basis of the embodiments of the present disclosure by a person of ordinary skill in the art without paying any creative effort shall be included in the protection scope of the present disclosure.

In an array substrate of an organic light-emitting diode (OLED) display, a pixel defining layer (PDL) is usually disposed on one side of a base substrate, and OLED functional films are usually formed in a pixel region of the pixel defining layer by an ink jet printing (IJP) process. The OLED functional films includes, for example, a light-emitting functional film. The pixel defining layer generally adopts a two-layer structure. That is, the pixel defining layer is a laminate of two materials having different wetting properties. Referring to FIG. 1, a first layer 21 of the pixel defining layer 2 adjacent to the base substrate 1 is formed from a lyophilic material, and a second layer 22 of the pixel defining layer 2 away from the base substrate 1 is formed from a lyophobic material.

In a process of manufacturing the above pixel defining layer 2, usually, a lyophilic material layer is first formed on one side of the base substrate 1, and patterned by a patterning process to form the first layer 21 of the pixel defining layer 2. Afterwards, a lyophobic material layer is formed on the lyophilic material layer, and patterned by a patterning process to form the second layer 22 of the pixel defining layer 2. Since the lyophilic material layer and the lyophobic material layer are formed from different materials, the lyophilic material layer and the lyophobic material layer may be incompatible with each other on a contact surface, causing the pixel defining layer 2 to be divided into two layers. Moreover, since the lyophilic material layer and the lyophobic material layer are patterned by two patterning processes, the lyophobic material layer patterned by the second patterning process is easily stacked at edges of patterned aperture regions of the lyophilic material layer due to deviations during pattern alignment. As a result, it is difficult to accurately define pixel regions in the pixel defining layer. Consequently, not only a film forming quality of the pixel defining layer 2 is poor, but also a surface of the pixel region tends to be uneven, making it difficult for each OLED functional film to be uniformly formed in the pixel region.

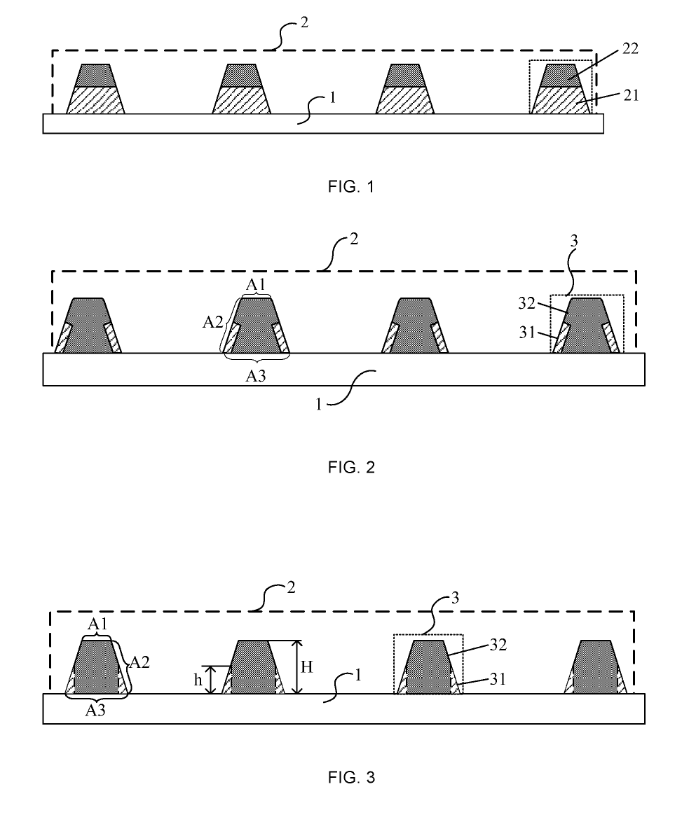

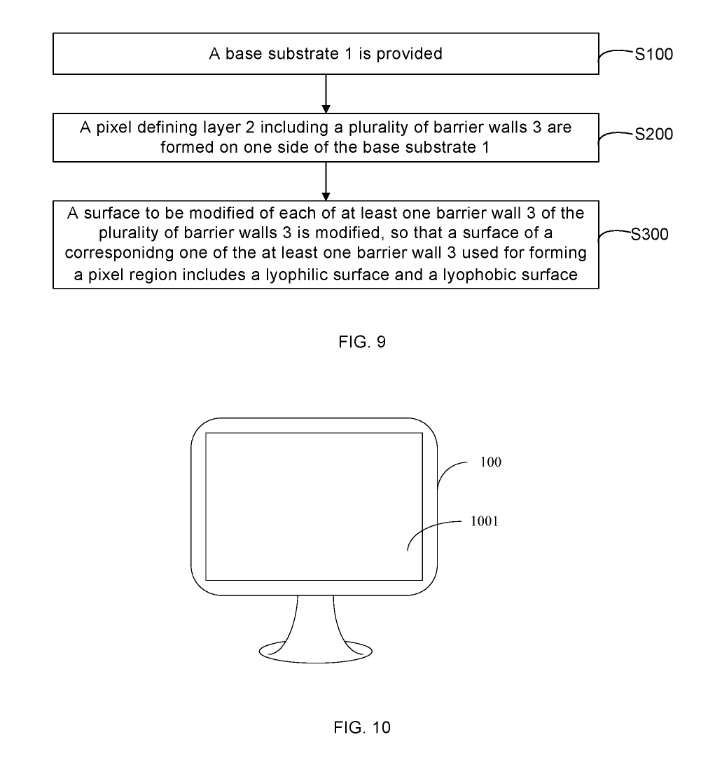

Based on this, some embodiments of the present disclosure provide a method of manufacturing an array substrate. As shown in FIGS. 2-9, the method includes step 100 (S100) to step 300 (S300).

In S100, a base substrate 1 is provided.

The base substrate 1 serves as a base for the array substrate, and electronic devices or circuit structure(s) are usually fabricated on a surface of the base substrate according to actual needs. Optionally, a pixel circuit layer is disposed on the surface of the base substrate, and the pixel circuit layer includes pixel driving circuits and driving electrodes correspondingly connected to the pixel driving circuit. Alternatively, the base substrate is a blank base substrate on which no electronic device or circuit structure is fabricated.

In S200, a pixel defining layer 2 including a plurality of barrier walls 3 are formed on one side of the base substrate 1.

The pixel defining layer 2 is configured to accurately define each pixel region. After the pixel defining layer 2 is patterned by a patterning process, the pixel defining layer 2 is generally presented as a structure composed of a plurality of barrier walls 3. That is, each pixel region of the pixel defining layer 3 is enclosed by corresponding barrier walls 3. A shape of a barrier wall 3 is determined according to actual needs. For example, the barrier wall 3 is strip-shaped, and a plurality of barrier walls 3 are staggered to form the pixel defining layer 2. Each pixel region of the pixel defining layer 2 is enclosed by four corresponding barrier walls 3. For another example, each barrier wall 3 is ring-shaped, and the plurality of barrier walls 3 are sequentially connected to form the pixel defining layer 2. Each pixel region of the pixel defining layer 2 is a region enclosed by a corresponding ring-shaped barrier wall 3.

The above description that the pixel defining layer 2 is formed on one side of the base substrate 1 includes the following situations. The pixel defining layer 2 is formed on a surface of the base substrate 1. Alternatively, the pixel defining layer 2 is formed on a surface of the pixel circuit layer away from the base substrate 1.

The patterning process mentioned above generally refers to a process for forming a predetermined pattern, such as a photolithographic process or an ink jet printing process. For example, the pixel defining layer 2 is patterned by a photolithographic process. The photolithographic process refers to a process of forming a pattern by using a tool or device such as a photoresist, a mask, and an exposure machine, and includes steps such as film formation, exposure, development, and etching.

In S300, a surface to be modified of each of at least one barrier wall 3 of the plurality of barrier walls 3 is modified, so that a surface of a corresponidng one of the at least one barrier wall 3 used for forming a pixel region includes a lyophilic surface and a lyophobic surface.

A modified surface, which is obtained after the surface to be modified is modified, of each of the at least one barrier wall 3 is a portion of the surface of the corresponding one of the at least one barrier wall 3 used for forming a pixel region. The surface to be modified is a portion of an original surface of the corresponding one of the at least one barrier wall 3 used for forming a pixel region, and the original surface is a surface that has not been modified.

Herein “modified” means to impart a new property such as a lyophilic or lyophobic property to the surface to be modified, under a premise of maintaining the initial property of the barrier wall. For example, a chemical method such as chemical coating or a physical method such as ion injection may be used to modify the surface to be modified, which is not limited by some embodiments of the present disclosure, and a suitable surface treatment method may be selected according to actual needs.

A material of the at least one barrier wall is a lyophilic material or a lyophobic material. Some embodiments of the present disclosure do not limit the material of the at least one barrier wall, but it is necessary to ensure that after the surface to be modified of each of the at least one barrier wall made from the material is modified, the modified surface has different a wetting property from the original surface. For example, the material of the at least one barrier wall is a lyophobic material, and the surface to be modified will be lyophilic after modification. For another example, the material of the at least one barrier wall is a lyophilic material, and the surface to be modified will be lyophobic after modification.

The surface of the at least one barrier wall used for forming a pixel region refers to a surface of the at least one barrier wall used for forming an aperture region in the pixel defining layer. The aperture region is the pixel region, and OLED functional films corresponding to a pixel will be formed in the aperture region. The surface to be modified of each of the at least one barrier wall is generally selected according to actual needs. For example, the at least one barrier wall is formed from a lyophobic material, and the surface to be modified is a portion, close to the base substrate, of the original surface of the at least one barrier wall used for forming a pixel region. For another example, the at least one barrier wall is formed from a lyophilic material, and the surface to be modified is a portion, away from the base substrate, of the original surface of the at least one barrier wall used for forming a pixel region.

Since modifying the surface to be modified of each of the at least one barrier wall is to perform surface treatment on the surface to be modified, i.e., to change a molecular chain or a chemical bond of the molecular chain of the surface to be modified, there will not be a contact surface between an unmodified portion of the barrier wall and an modified portion of the barrier wall. Therefore, the barrier wall will not be divided into layers. That is, there will not be such a problem that the pixel defining layer is divided into layers. In some embodiments of the present disclosure, there will not be an interlayer contact surface between the unmodified portion and the modified portion of the at least one barrier wall of the pixel defining layer. The lyophilic surface and the lyophobic surface of each of the at least one barrier wall is formed by one patterning process and one surface modification process, therefore there will not be such a problem that film layers of the pixel defining layer are stacked due to use of two separate patterning processes. Therefore, with this method, it may be possible to accurately define each pixel region in the pixel defining layer, and thus improve the film forming quality of the pixel defining layer, and ensure that the OLED functional film layer is uniformly formed in a corresponding pixel region of the pixel defining layer.

Moreover, after the surface to be modified of each of the at least one barrier wall is modified according to the method of manufacturing an array substrate, the surface of a corresponding one of the at least one barrier wall used for forming a pixel region will include both a lyophilic surface and a lyophobic surface. As a result, when forming OLED functional films in a pixel region enclosed by multiple barrier walls in the pixel defining layer, since the lyophilic surface and the lyophobic surface have different adhesion to ink jet droplets forming the OLED functional films, it may be ensured that the OLED functional films are properly formed in a region corresponding to the lyophilic surface of the at least one barrier wall, and that each OLED functional film have a uniform thickness.

As mentioned above, a chemical method such as chemical coating or a physical method such as ion injection is used to modify the surface.

In some embodiments, referring to FIG. 2, a chemical method such as chemical coating is used to modify the surface, and the above step 300 in which a surface to be modified of each of at least barrier wall is modified includes step 301 (S301) to step 303 (S303).

In S301, a photoresist is sprayed on the original surface of each of the at least one barrier wall 3 used for forming a pixel region, and the photoresist is exposed and developed, so that the surface to be modified of a corresponding one of the at least one barrier wall 3 is exposed.

In S302, a chemical reagent is used to chemically react with the exposed surface to be modified of the corresponding one of the at least one barrier wall 3 to modify the wetting property of the exposed surface to be modified.

In S303, the photoresist is striped.

The surface of each of the at least one barrier wall 3 used for forming a pixel region has different wetting properties, for example, lyophilic and lyophobic properties. That is to say, the surface of each of the at least one barrier wall 3 used for forming a pixel region includes a lyophilic surface 31 and a lyophobic surface 32.

Of course, the step 300, in which the surface to be modified of the corresponding one of the at least one barrier wall of the plurality of barrier walls is modified, may also be implemented in other ways. For example, referring to FIG. 3-8, a physical method such as ion injection is used for modifying the surface to be modified, and the step 300, in which the surface to be modified of the corresponding one of the at least one barrier wall 3 of the plurality of barrier walls is modified, includes step 301′ (S301′) and step 302′ (S302′).

In S301′, a mask 4 is provided on a surface of the at least one barrier wall 3 facing away from the base substrate 1. The mask 4 includes at least one opening and at least one shield protion, and an orthographic projection of the surface to be modified of each of the at least one barrier wall 3 on the base substrate 1 is within an orthographic projection of a corresponding one of the at least one opening of the mask 4 on the base substrate 1.

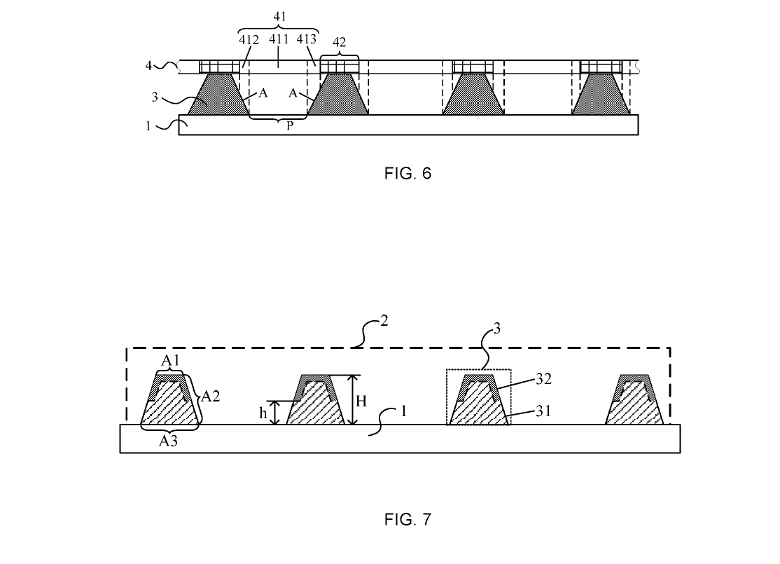

Referring to FIGS. 5 and 6, the mask 4 provided in S301′ includes openings 41 and shield protions 42. A opening 41 of the mask 4 is generally disposed according to a corresponding surface to be modified A of the at least one barrier wall 3. For example, a portion, through which the plasma passes, of the mask 4 that is disposed directly facing a surface to be modified A is set as the opening 41. That is, an orthographic projection of the surface to be modified A of the at least one barrier wall 3 on the base substrate 1 is within an orthographic projection of the opening 41 of the mask 4 on the base substrate 1. Correspondingly, a shield protion 42 of the mask 4 is generally disposed according to a position of a non-modified surface of the at least one barrier wall 3. For example, a protion of the mask 4 that is disposed directly facing the non-modified surface and blocks the plasma from passing through is set as the shield protion 42. That is, an orthographic projection of the non-modified surface of the at least one barrier wall 3 on the base substrate 1 is within an orthographic projection of the shield protion 42 of the mask 4 on the base substrate 1.

In addition, portions of the mask 4 directly facing other regions of the pixel defining layer except for the at least one barrier wall 3 may be set as either openings 41 or shield protions 42. Optionally, as shown in FIG. 6, the surface to be modified A of each of the at least one barrier wall 3 is connected to a bottom border of the corresponding one of the at least one barrier wall 3 (in some embodiments, the surface to be modified of each of the at least one barrier wall 3 is connected to a top surface of the corresponding one of the at least one barrier wall 3), it is arranged that a portion of the mask 4 directly facing a connecting region P between the surface to be modified A and an adjacent barrier wall is a opening 411. That is, both the orthographic projection of the surface to be modified A of the at least one barrier wall 3 on the base substrate 1 and an orthographic projection of the connecting region P among the surface to be modified A and adjacent barrier walls 3 adjacent to the surface to be modified A on the base substrate 1 are within the orthographic projection of the opening 41 of the mask 4 on the base substrate 1.

Since the connecting region P is defined by a bottom border of the barrier wall 3 where the surface to be modified A connected to the connecting region P is located and bottom borders of adjacent barrier walls 3, and the surface to be modified of the barrier wall 3 where the surface to be modified A is located is connected to the bottom border of the barrier wall 3, the opening 41 of the mask 4 located in a same pixel region is an entire opening. That is, the opening 41 of the mask 4 located in a same pixel region includes a first opening 411 of the mask 4 directly facing the connecting region P, and a second opening 412 and a third opening 413 of the mask 4 directly facing the surfaces to be modified A adjacent to the connecting region P. For example, the connecting region P is enclosed by four corresponding barrier walls 3, and the opening 41 of the mask 4 located in a same pixel region includes a first opening 411 of the mask 4 directly facing the connecting region P, and four openings of the mask 4 directly facing the surfaces to be modified A of the four corresponding barrier walls 3. For another example, the connecting region P is enclosed by one corresponding barrier wall 3, and the opening 41 of the mask 4 located in a same pixel region includes a first opening 411 of the mask 4 directly facing the connecting region P, and an opening of the mask 4 directly facing the surface to be modified A of the barrier walls 3. Thus when using the mask 4 shown in FIG. 6 to inject plasma into the surface to be modified A of the barrier wall 3, the plasma passing through the first opening 411 is injected into a surface of the connecting region P, removing impurities and residual particles on the surface of the connecting region P. Meanwhile, lyophilic properties of the surface of the connecting region P may be improved to a certain extent. As a result, in a case where each OLED functional film is printed by ink jet printing, it may be ensured that the ink jet droplets are better dispersed on the surface of the connecting region P and the modified surface of the surface to be modified A, which in turn improves uniformity of the OLED functional films.

In S302′, plasma is injected into the surface to be modified of each of the at least one barrier wall 3 exposed in the opening of the mask 4, so as to modify the wetting property of the surface to be modified, so that the surface of a corresponding one of the at least one barrier wall 3 used for forming a pixel region has different wetting properties. That is, the surface of the at least one barrier wall 3 used for forming a pixel region includes a lyophilic surface 31 and a lyophobic surface 32.

In a case where a plasma injection method is used for modifying the surface to be modified, the plasma is capable of entering a certain depth below the surface to be modified. An injection depth of the plasma is generally related to an energy of the plasma. By accelerating the plasma to different velocities, it is possible to obtain modified layers having different thicknesses. Some embodiments of the present disclosure does not limit the injection depth of the plasma, as long as the surface to be modified of the at least one barrier wall meets the requirements of use after modification.

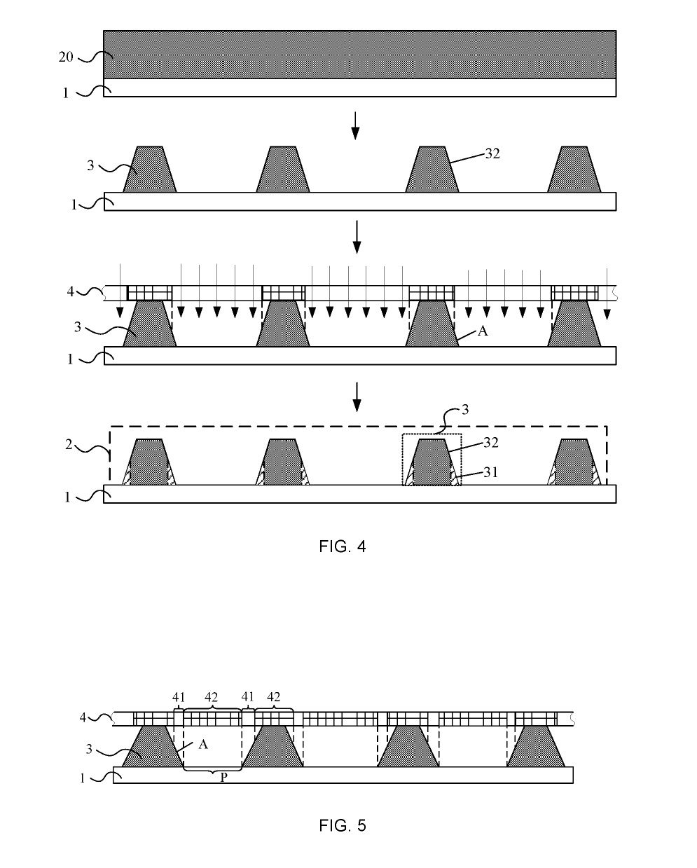

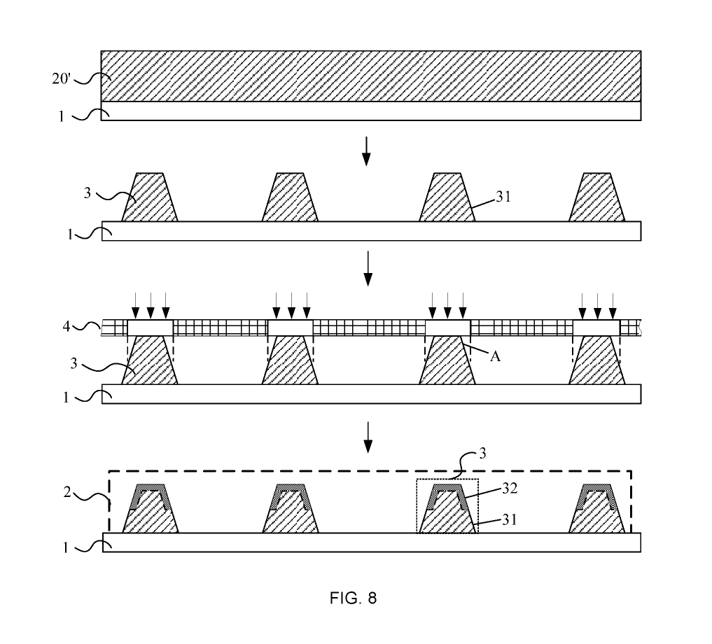

In some embodiments, the mask 4 is a contact mask. That is, a surface of the mask 4 close to the base substrate 1 is in a same plane as the top surface of the at least one barrier wall 3 away from the base substrate 1. In this way, the mask 4 is in contact with, or considered to be in contact with, the top surface of each of the at least one barrier wall 3 away from the base substrate 1. For example, referring to FIG. 4, at least one shield protion of the mask 4 is directly facing at least one top surface of the at least one barrier wall 3 away from the base substrate 1 directly. In a case where an orthographic projection of the top surface of each of the at least one barrier wall 3 on the base substrate 1 is within the orthographic projection of a corresponding shield protion of the mask 4 on the base substrate 1, the shield protion of the mask 4 is in direct contact with the top surface of the barrier wall 3 away from the base substrate 1. For another example, referring to FIG. 8, a shield protion of the mask 4 is directly facing a corresponidng pixel region of the pixel defining layer 2. In a case where the orthographic projection of the pixel region on the base substrate 1 is within the orthographic projection of the shield protion of the mask 4 on the base substrate 1, the shield protion of the mask 4 will be considered to be in contact with the top surface of the at least one barrier wall 3 away from the base substrate 1. Some embodiments of the present disclosure adopt a contact mask, which may effectively reduce a diffraction effect of the plasma and accurately control a motion trajectory of the plasma, thereby ensuring a surface modification quality of the surface to be modified of a corresponding barrier wall. In some embodiments of the present disclosure, a critical dimension bias (CD bias) of the mask 4 is controlled to be within 0.25 μm, which may further improve the surface modification quality of the surface to be modified of the barrier wall.

It will be understood that, in a case where a chemical method such as chemical coating or a physical method such as ion injection is used for modifying the surface, although a material of the barrier walls in the pixel defining layer is not limited, a method of manufacturing a corresponding array substrate will be slightly different depending on whether the barrier walls in the pixel defining layer are formed from a lyophobic material or a lyophilic material. A description is given below by taking an example in which the ion injection method is used for modifying the surface. It will be understood that, in a case where other methods are used for modifying the surface, it is possible to make an adaptive change or no change in modifying a lyophilic material surface or a lyophobic material surface according to a principle and usual practice of each method.

In some embodiments, referring to FIGS. 2-4, the plurality of barrier walls 3 of the pixel defining layer 2 are formed from a lyophobic material. The lyophobic material generally has a small surface energy and a large contact angle, and a type of the lyophobic material is not limited by some embodiments of the present disclosure. For example, the lyophobic material is selected from a group consisting of fluorinated polyimide, fluorinated polymethyl methacrylate, polysiloxane, and combination thereof. The step 300, in which the surface to be modified of each the at least one barrier wall is modified, includes: performing lyophilic treatment on the surface to be modified of each of the at least one barrier wall 3.

There may be many ways to perform lyophilic treatment, and a suitable treatment method is usually selected according to actual needs. Optionally, referring to FIG. 4, the step of performing lyophilic treatment on the surface to be modified of each of the at least one barrier wall 3 includes: injecting at least one of O₂ plasma, N₂ plasma, or NH₃ plasma into the surface to be modified A of each of the at least one barrier wall 3, so as to modify the surface to be modified A of each of the at least one barrier wall 3 from a lyophobic surface to a lyophilic surface. The type of plasma is not limited to this, and other plasmas capable of modifying a lyophobic surface to a lyophilic surface are suitable.

For example, referring to FIG. 4, a method of manufacturing an array substrate provided by some embodiments of the present disclosure is detailed below. In this method, the surface to be modified of each barrier wall 3 is subjected to lyophilic treatment.

First, a layer of an organic polymer material having a lyophobic property is formed on the base substrate 1, and the organic polymer material is fluorinated polyimide.

A precursor solution of fluorinated polyimide is coated on the surface of the base substrate 1 by spin coating, and is pre-cured by baking to form an organic polymer material layer. A curing temperature is approximately 50° C.˜120° C., and a baking time is approximately 5 min˜30 min, which may be determined according to actual needs.

Then, the organic polymer material layer is patterned by a photolithographic process to form a pixel defining layer. The pixel defining layer is formed by connecting a plurality of connected barrier walls 3. The height of each barrier wall 3 is a thickness of the pixel defining layer, and the thickness of the pixel defining layer is approximately 1 μm˜5 μm.

As for the photolithographic processes, a dry etching process is adopted. That is, the pre-cured organic polymer material layer is etched by an etching gas such as CF₄ or O₂, and subjected to post-baking annealing treatment after the etching process. An annealing temperature is approximately 160° C.˜220° C., and an annealing time is approximately 15 min˜60 min.

Finally, the contact mask 4 is used to inject plasma into the surface to be modified A of each barrier wall 3 in the pixel defining layer, so as to convert the surface to be modified A from an initial lyophobic surface to a lyophilic surface.

The contact mask 4 adopts a structure as shown in FIG. 6. The shield protion 42 of the mask 4 is in contact with a portion such as the top surface of the non-modified surface of each barrier wall 3, so as avoid the diffraction effect of the plasma. Both an orthographic projection of the surface to be modified A on the base substrate 1 and an orthographic projection of the connecting region P between the surface to be modified A and adjacent barrier walls 3 on the base substrate 1 are within an orthographic projection of the opening 41 of the mask 4 on the base substrate 1. The plasma is O₂ plasma, and the plasma injection time is approximately 3 min˜30 min. The O₂ plasma is capable of converting the C—F bond of the surface to be modified A of each barrier wall 3 formed from fluorinated polyimide into a C—O bond, i.e., ensuring that the surface to be modified A is converted from a lyophobic surface to a lyophilic surface. Optionally, in a case where a height of each barrier wall 3 is 1 μm˜5 μm and the bottom surface of each barrier wall 3 close to the base substrate 1 is used as a reference surface, the surface to be modified of each barrier wall 3 having a height less than 0.1 μm˜0.5 μm is modified to a lyophilic surface 31.

In some embodiments, referring to FIGS. 7-8, the plurality of barrier walls 3 of the pixel defining layer 2 are made from a lyophilic material. The lyophilic material generally has a large surface energy and a small contact angle, and a type of the lyophilic material is not limited by some embodiments of the present disclosure. For example, the lyophilic material is selected from a group consisting of a starch polymer, a cellulose polymer, a polyvinyl alcohol polymer, a polyacrylate polymer, a polyoxyethylene polymer, and combination thereof. The step 300, in which the surface to be modified of each of the at least one barrier wall is modified, includes: performing lyophobic treatment on the surface to be modified of each of the at least one barrier wall 3.

There may be many ways to perform lyophobic treatment, and a suitable treatment method is usually selected according to actual needs. Optionally, referring to FIG. 8, the step of performing lyophobic treatment on the surface to be modified of each of the at least one barrier wall 3 includes: injecting at least one of NF₃ plasma, CF₄ plasma, or SF₆ plasma into the surface to be modified A of each of the at least one barrier wall 3, so as to modify the surface to be modified A of each of the at least one barrier wall 3 from a lyophilic surface to a lyophobic surface. The type of plasma is not limited to this, and other plasmas capable of modifying a lyophilic surface to a lyophobic surface are suitable.

For example, referring to FIG. 8, a method of manufacturing an array substrate provided by some embodiments of the present disclosure is detailed below. In this method, the surface to be modified of each barrier wall 3 is subjected to lyophobic treatment.

First, a layer of an organic polymer material having a lyophilic property is formed on the base substrate 1, and the organic polymer material is polyvinyl alcohol polymer.

A precursor solution of polyvinyl alcohol polymer is coated on the surface of the base substrate 1 by spin coating, and is pre-cured by baking to form an organic polymer material layer. The curing temperature is approximately 50° C.˜120° C., and the baking time is approximately 5 min˜30 min, which may be determined according to actual needs.

Then, the above organic polymer material layer is patterned by a photolithographic process to form a pixel defining layer. The pixel defining layer is formed by connecting a plurality of barrier walls 3. The height of each barrier wall 3 is a thickness of the pixel defining layer, and the thickness of the pixel defining layer is approximately 1 μm˜5 μm.

As for the photolithographic processes, a dry etching process is adopted. That is, the pre-cured organic polymer material layer is etched by an etching gas such as CF₄ or O₂, and subjected to post-baking annealing treatment after the etching process. The annealing temperature is approximately 160° C.˜220° C., and the annealing time is approximately 15 min˜60 min.

Finally, the contact mask 4 is used to inject plasma into the surface to be modified A of each barrier wall 3 in the pixel defining layer, so as to convert the surface to be modified A from an initial lyophilic surface to a lyophobic surface.

The surface to be modified A of each barrier wall 3 in the pixel defining layer is a portion of the original surface of the barrier wall 3 close to a top surface thereof, and the top surface of the barrier wall 3 may be modified or not. The contact mask 4 is disposed on the surface of the pixel defining layer 2 facing away from the base substrate 1. That is, a bottom surface of the contact mask 4 close to the base substrate 1 is in a same plane as the top surface of each barrier wall 3 of the pixel defining layer 2 away from the base substrate 1, and the contact mask 4 is considered to be in contact with the top surface of each barrier wall 3. The opening of the mask 4 is directly facing the surface to be modified A of each barrier wall 3. The plasma is CF₄ plasma, and the plasma injection time is approximately 3 min˜30 min. The CF₄ plasma is capable of converting the C—O bond of the surface to be modified A of each barrier wall 3 formed from polyvinyl alcohol polymer into a C—F bond, i.e., ensuring that the surface to be modified A is converted from a lyophilic surface to a lyophobic surface. Optionally, in a case where a height of each barrier wall 3 is 1 μm˜5 μm and the bottom surface of each barrier wall 3 close to the base substrate 1 is used as a reference surface, the surface to be modified of each barrier wall 3 having a height greater than 0.1 μm˜0.5 μm is modified to a lyophobic surface 32.

Some embodiments of the present disclosure provide an array substrate, which is formed by the method of manufacturing an array substrate described by some embodiments above. Referring to FIGS. 2, 3 and 7, the array substrate includes a base substrate 1 and a pixel defining layer 2 disposed on one side of the base substrate 1. The pixel defining layer includes a plurality of barrier walls 3, a surface of each of at least one barrier wall 3 of the plurality of barrier walls 3 used for forming a pixel region includes a lyophilic surface 31 and a lyophobic surface 32, and one of the lyophilic surface 31 and the lyophobic surface 32 is a modified surface.

The above base substrate 1 serves as a base for the array substrate, and the array substrate further includes electronic devices or circuit structure(s) disposed on the surface of the base substrate 1 according to actual needs. Alternatively, the base substrate 1 is a blank base substrate on which no electronic device or circuit structure is disposed. Optionally, the array substrate includes a pixel circuit layer disposed on the surface of the base substrate 1, and the pixel circuit layer includes pixel driving circuits and driving electrodes correspondingly connected to the pixel driving circuits. The pixel defining layer 2 is formed on a surface of the pixel circuit layer facing away from the base substrate 1. The plurality of barrier walls 3 are connected to form the pixel defining layer 2, and each pixel region of the pixel defining layer 2 is enclosed by corresponding barrier walls 3.

The surface of each of the at least one barrier wall 3 used for forming a pixel region refers to a surface of each of the at least one barrier wall 3 used for forming an aperture region in the pixel defining layer. The aperture region is the pixel region, and the surface includes a lyophilic surface 31 and a lyophobic surface 32. As a result, when forming OLED functional films in a pixel region enclosed by multiple barrier walls 3 in the pixel defining layer 2, since the lyophilic surface 31 and the lyophobic surface 32 have different adhesion to ink jet droplets forming each OLED functional film, it may be ensured that each OLED functional film is properly formed in a region corresponding to the lyophilic surface 31 of the at least one barrier wall 3, and that each OLED functional film has a uniform thickness.

The above description that one of the lyophilic surface 31 and the lyophobic surface 32 of the at least one barrier wall 3 is a modified surface means that one of the lyophilic surface 31 and the lyophobic surface 32 of the at least one barrier wall 3 is obtained through a surface modification process. For example, referring to FIGS. 2 and 3, the plurality of barrier walls 3 are formed from a lyophobic material, original surfaces of the barrier walls 3 are all lyophobic surfaces, and lyophilic surfaces 31 need to be obtained through a surface modification process. For another example, referring to FIG. 7, the plurality of barrier walls 3 are formed from a lyophilic material, original surfaces of the barrier walls 3 are all lyophilic surfaces, and lyophobic surfaces 32 need to be obtained through a surface modification process. Some embodiments of the present disclosure do not limit types of the lyophobic material and the lyophilic material. The lyophobic material generally has a small surface energy and a large contact angle, and the lyophilic material generally has a large surface energy and a small contact angle. No matter whether the plurality of barrier walls 3 are made from a lyophobic material or a lyophilic material, optionally, the lyophilic surface 31 of each of the plurality of barrier walls 3 includes at least one of a C—O bond, a C—N bond or a C—H bond, and the lyophobic surface 32 of each of the plurality of the barrier walls 3 includes at least one of a C—F bond or a C—Si bond.

Since one of the lyophilic surface 31 and the lyophobic surface 32 of each of the at least one barrier wall 3 is obtained after the surface to be modified of the at least one barrier wall 3 is modified, there will not be a contact surface between an unmodified surface and an modified surface of each of the at least one barrier wall 3. Therefore, the barrier wall will not be divided into layers. That is, there will not be such a problem that the pixel defining layer is divided into layers. In some embodiments of the present disclosure, there will not be an interlayer contact surface between the unmodified surface and the modified surface of each of the at least one barrier wall of the pixel defining layer. The lyophilic surface and the lyophobic surface of each of the at least one barrier wall is formed by one patterning process and one surface modification process, therefore there will not be such a problem that film layers of the pixel defining layer are stacked due to use of two separate patterning processes. Therefore, with this method, it may be possible to accurately define each pixel region in the pixel defining layer, and thus improve the film forming quality of the pixel defining layer, and ensure that the OLED functional film layers are uniformly formed in pixel regions of the pixel defining layer.

It will be understood that, since the OLED functional films are formed in the pixel region of the pixel defining layer 2, the lyophilic surface 31 of a barrier wall is bordered by the lyophobic surface 32 of the same barrier wall 3, and the lyophilic surface 31 is located on a side of the lyophobic surface 32 close to the base substrate 1, the OLED functional films are formed in a region corresponding to the lyophilic surface 31 of the barrier wall 3.

For example, referring to FIGS. 2, 3 and 7, the plurality of barrier walls 3 in the pixel defining layer 2 generally adopt a trapezoidal structure, and surfaces of the barrier wall 3 include a top surface A1, a bottom surface A3, and a side surface A2 connecting the top surface A1 and the bottom surface A3. In a case where a surface of each of the at least one barrier wall 3 adjacent to the base substrate 1, i.e., a bottom surface A3 of a corresponding barrier wall 3, is used as a reference surface, in a direction from the base substrate 1 to the at least one barrier wall 3, if a height of one of the at least one barrier wall is a first height H, a height of a border between the lyophilic surface 31 and the lyophobic surface 32 of the one of the at least one barrier wall is a second height h, then the second height h is 5%˜20% of the first height H. Alternatively, the second height h is approximately 5%˜20% of the first height H.

Referring to FIGS. 2, 3 and 7, the side surface A2 of the barrier wall 3 is a surface of the barrier wall 3 close to adjacent barrier walls 3. A side surface A2 of a barrier wall 3 includes a lyophilic surface 31 and a lyophobic surface 32 bordering each other. The lyophilic surface 31 is a portion of the side surface A2 of the barrier wall 3 close to the base substrate 1, and the lyophobic surface 32 is a portion of the side surface A2 of the barrier wall 3 away from the base substrate 1. Optionally, the height of each barrier wall 3 of the pixel defining layer 2, i.e., the first height H, is 1 μm˜5 μm. Alternatively, the first height H is approximately 1 μm˜5 μm. The height of the border between the lyophilic surface 31 and the lyophobic surface 32 of each barrier wall 3, i.e., the second height h, is 0.1 μm˜0.5 μm. Alternatively, the second height h is approximately 0.1 μm˜0.5 μm.

If the second height h is less than 0.1 μm, in a case where the OLED functional films are formed by ink jet printing, since an area of the lyophilic surface 31 of the side surface A2 of each barrier wall 3 is small, the ink jet droplets are easily to be in poor contact with the side surface A2 of each barrier wall 3, which is disadvantageous for effectively ensuring the uniformity of each OLED functional film layer. If the second height h is greater than 0.5 μm, in a case where the OLED functional films are formed by ink jet printing, since the area of the lyophilic surface 31 of the side surface A2 of each barrier wall 3 is large, the ink jet droplets will easily climb up along the side surface A2 of each barrier wall 3, resulting in poor uniformity of each OLED functional film. It can be seen that the second height h, i.e., the height of the border between the lyophilic surface 31 and the lyophobic surface 32 of each barrier wall 3, needs to be determined according to the thickness of the pixel defining layer 2, i.e., the height H of each barrier wall 3. In some embodiments, the first height H is approximately 5 μm, the second height h is 0.2 μm or 0.3 μm.

In addition, since one of the lyophilic surface 31 and the lyophobic surface 32 of each of the at least one barrier wall 3 is obtained through a surface modification process, which affects a certain depth of material below the surface, modification is not limited to the material at the surface of each of the at least one barrier wall 3, but the material on the surface and near the surface of each of the at least one barrier wall 3 will be different from a host material of each of the at least one barrier wall 3 after the modification. However, the material on the surface and near the surface of each of the at least one barrier wall 3 that are modified and the host material of each of the at least one barrier wall 3 have the same polymer backbone, but different branched chemical bonds and branched functional groups. That is, if it needs to be determined whether a surface of a certain barrier wall 3 is a modified surface, just see if the material of a portion of the surface of the barrier wall 3 and the host material of the barrier wall 3 have the same polymer backbone but different branched chemical bonds or branched functional groups: if yes, it may be determined that the portion of surface of the barrier wall 3 is a modified surface. The host material of the barrier wall 3 refers to the material located near the geometric center of the barrier wall 3, and is also the initial material of the barrier wall 3.

As shown in FIG. 10, some embodiments of the present disclosure provide a display panel 1001, which includes the array substrate described above. The display panel has a same structure and advantageous effects as the array substrate provided by the above embodiments, and details are not described herein again.

As shown in FIG. 10, some embodiments of the present disclosure provide a display device 100, which includes the display panel 1001 described above. The display device has a same structure and advantageous effects as the display panels provided by the above embodiments, and details are not described herein again. In addition, for example, the above display device is an OLED display panel, an OLED display, an OLED television, a cellphone, a tablet computer, a notebook computer, an electronic paper, a digital photo frame, a navigator, or any product or component having a display function.

In the description of the above embodiments, specific features, structures, materials or characteristics may be combined in any suitable manner in any one or more embodiments or examples.

The foregoing descriptions are merely some implementation manners of the present disclosure, but the protection scope of the present disclosure is not limited thereto. Any person skilled in the art could readily conceive of changes or replacements within the technical scope of the present disclosure, which shall all be included in the protection scope of the present disclosure. Therefore, the protection scope of the present disclosure shall be subject to the protection scope of the claims.

What is claimed is:

1. A method of manufacturing an array substrate, comprising:
providing a base substrate;
forming a pixel defining layer including a plurality of barrier walls on one side of the base substrate; and
modifying a surface to be modified of each of at least one barrier wall of the plurality of barrier walls, so that a surface of a corresponidng one of the at least one barrier wall used for forming a pixel region includes a lyophilic surface and a lyophobic surface.

2. The method of manufacturing an array substrate according to claim 1, wherein modifying a surface to be modified of each of at least one barrier wall, comprises:
providing a mask on a surface of the at least one barrier wall facing away from the base substrate, wherein the mask comprises at least one opening, and an orthographic projection of the surface to be modified of each of the at least one barrier wall on the base substrate is within an orthographic projection of a corresponding one of the at least one opening of the mask on the base substrate; and
injecting plasma into the surface to be modified of each of the at least one barrier wall exposed in the corresponding one of the at least one opening of the mask, so as to modify a wetting property of the surface to be modified.

3. The method of manufacturing an array substrate according to claim 2, wherein a surface of the mask close to the base substrate is in a same plane as a top surface of the at least one barrier wall away from the base substrate.

4. The method of manufacturing an array substrate according to claim 1, wherein
the plurality of barrier walls are formed from a lyophobic material; and
modifying a surface to be modified of each of at least one barrier wall, comprises:
performing lyophilic treatment on the surface to be modified of each of the at least one barrier wall.

5. The method of manufacturing an array substrate according to claim 4, wherein the lyophobic material is selected from a group consisting of fluorinated polyimide, fluorinated polymethyl methacrylate, polysiloxane, and combination thereof.

6. The method of manufacturing an array substrate according to claim 4, wherein performing lyophilic treatment on the surface to be modified of each of the at least one barrier wall, comprises:
injecting at least one of O₂ plasma, N₂ plasma, or NH₃ plasma into the surface to be modified of each of the at least one barrier wall, so as to modify the surface to be modified of each of the at least one barrier wall from a lyophobic surface to a lyophilic surface.

7. The method of manufacturing an array substrate according to claim 1, wherein
the plurality of barrier walls are formed from a lyophilic material; and
modifying a surface to be modified of each of at least one barrier wall, comprises:
performing lyophobic treatment on the surface to be modified of each of the at least one barrier wall.

8. The method of manufacturing an array substrate according to claim 7, wherein the at least one lyophilic material is selected from a group consisting of a starch polymer, a cellulose polymer, a polyvinyl alcohol polymer, a polyacrylate polymer, a polyoxyethylene polymer, and combination thereof.

9. The method of manufacturing an array substrate according to claim 7, wherein performing lyophobic treatment on the surface to be modified of each of the at least one barrier wall, comprises:
injecting at least one of NF₃ plasma, CF₄ plasma, or SF₆ plasma into the surface to be modified of each of the at least one barrier wall, so as to modify the surface to be modified of each of the at least one barrier wall from a lyophilic surface to a lyophobic surface.

10. The method of manufacturing an array substrate according to claim 1, wherein modifying a surface to be modified of each of at least one barrier wall, comprises:
spraying a photoresist on an original surface of each of the at least one barrier wall used for forming a pixel region, and exposing and developing the photoresist so that the surface to be modified of each of the at least one barrier wall is exposed; and
using a chemical reagent to chemically react with the exposed surface to be modified of each of the at least one barrier wall to modify a wetting property of the surface to be modified.

11. An array substrate, comprising:
a base substrate; and
a pixel defining layer disposed on one side of the base substrate, wherein
the pixel defining layer includes a plurality of barrier walls, a surface of each of at least one barrier wall of the plurality of barrier walls used for forming a pixel region includes a lyophilic surface and a lyophobic surface, and one of the lyophilic surface and the lyophobic surface is a modified surface.

12. The array substrate according to claim 11, wherein the lyophilic surface of each of the at least one barrier wall is bordered by the lyophobic surface of a same barrier wall, and the lyophilic surface is disposed on a side of the lyophobic surface close to the base substrate.

13. The array substrate according to claim 12, wherein a surface of each of the at least one barrier wall close to the base substrate is used as a reference surface, in a direction from the base substrate to the at least one barrier wall, a height of one of the at least one barrier wall is a first height, a height of a border between the lyophilic surface and the lyophobic surface of the one of the at least one barrier wall is a second height; and
the second height is 5%˜20% of the first height; or, the second height is approximately 5%˜20% of the first height.

14. The array substrate according to claim 13, wherein
the first height is 1 μm˜5 μm; or, the first height is approximately 1 μm˜5 μm;
the second height is 0.1 μm˜0.5 μm, or, the second height is approximately 0.1 μm˜0.5 μm.

15. The array substrate according to claim 11, wherein the lyophilic surface of each of the at least one barrier wall includes at least one of a C—O bond, a C—N bond, or a C—H bond.

16. The array substrate according to claim 11, wherein the lyophobic surface of each of the at least one barrier wall includes at least one of a C—F bond or a C—Si bond.

17. A display panel, comprising the array substrate according to claim 11.

18. A display device, comprising the display panel according to claim 17.
